(19) United States
(12) Patent Application Publication
(10) Pub. No.: US 2011/0032622 A1
(43) Pub. Date: Feb. 10, 2011

(54) OPTICAL FILTER FOR DISPLAY DEVICE

(75) Inventors: Jong Taek Kim, ChungCheongNam-Do (KR); Sang Yoon Oh, ChungCheongNam-Do (KR); Dae Chul Park, ChungCheongNam-Do (KR); Ji Young Kim, ChungCheongNam-Do (KR); Jung Hong Oh, ChungCheongNam-Do (KR); Gi Mo Yang, ChungCheongNam-Do (KR); Ji Yoon Seo, ChungCheongNam-Do (KR); Dong Hyun Park, ChungCheongNam-Do (KR); Kun Yong Jang, ChungCheongNam-Do (KR); Seok Won Kim, ChungCheongNam-Do (KR)

Correspondence Address: LERNER, DAVID, LITTENBERG,;KRUMHOLZ & MENTLIK, 600 SOUTH AVENUE WEST, WESTFIELD, NJ, 07090, US

(73) Assignee: SAMSUNG CORNING PRECISION GLASS CO., LTD., Gyeongsangbuk-do (KR)

(21) Appl. No.: 12/637,061

(22) Filed: Dec. 14, 2009

(30) Foreign Application Priority Data
Aug. 7, 2009 (KR) 10-2009-0072796
Sep. 10, 2009 (KR) 10-2009-0085370

(51) Int. Cl. G02B 27/00; H05K 9/00

(52) U.S. Cl. 359/609; 361/818

(57) ABSTRACT

An optical filter for a display device includes a base substrate, an EMI shielding coating formed directly on an upper surface of the base substrate to filter EMI, and a color control resin coating applied directly on a lower surface of the base substrate or an upper surface of the EMI shielding coating. Due to the EMI shielding coating and the color control resin coating formed directly on the base substrate, it is possible to simplify a manufacturing process, improve productivity, and reduce manufacturing costs.

### CROSS REFERENCE TO RELATED APPLICATION

The present application claims priority from Korean Patent Application Numbers 10-2009-0072796 and 10-2009-0085370 filed on Aug. 7, 2009 and Sep. 10, 2009, respectively, the entire contents of which are incorporated herein for all purposes by this reference.

### BACKGROUND OF THE INVENTION

1. Field of the Invention

The present invention relates to an optical filter for a display device, and more particularly, to an optical filter for a display device in which functional layers having respective functions are formed directly on a base substrate, thereby simplifying a fabrication process and reducing manufacturing costs.

2. Description of Related Art

In modern society, display devices for displaying images have been widely used.

A Plasma Display Panel (PDP) device charges a direct or alternating voltage to electrodes in cells full of gas, which generates Ultraviolet (UV) radiation, so that the UV radiation in turn activates a fluorescent material to thereby emit visible light. However, the PDP device disadvantageously generates Electromagnetic Interference (EMI), which is harmful to the human body, Near-Infrared (NIR) radiation, which may cause a remote control or the like to malfunction, orange neon light, which deteriorates color purity, etc.

Accordingly, the PDP device is provided with a PDP optical filter that has a variety of functions, such as EMI shielding, NIR cutting, reflection prevention, and/or color purity improvement, in order to block EMI and NIR, reduce the reflection of light, and improve color purity.

FIG. 1 is a cross-sectional view showing an optical filter for a display device of the related art.

The optical filter for the display device of the related art has a stacked structure in which a base substrate 110, an EMI shielding film 120, a color control film 130, an NIR cutting film 140, and an anti-reflection film 150 are stacked on one another.

The EMI shielding film 120 is stacked on one side of the base substrate 110, whereas the color control film 130, the NIR cutting film 140, and the anti-reflection film 150 are stacked on the other side of the base substrate 110 via respective adhesion layers.

Describing the structure of the respective films, the EMI shielding film 120 has a transparent support film 122 with an EMI shielding layer 124 formed on one side of the transparent support film 122, the color control film 130 has a transparent support film 132 with a color control layer 134 formed on one side of the transparent support film 132, the NIR cutting film 140 has a transparent support film 142 with an NIR cutting layer 144 formed on one side of the transparent support film 142, and the anti-reflection film 150 has a transparent support film 152 with a reflection-preventing layer 154 formed on one side of the transparent support film 152.

In the optical filter for the display device of the related art as described above, the respective films need the transparent support films 122, 132, 142, and 152, and the EMI shielding film, the anti-reflection film, the NIR cutting film, the color control film, etc. are stacked on one or the other side of the base substrate 110 via the respective adhesion layers. Accordingly, the optical filter entails a complicated fabrication process, which consequently lowers productivity and increases manufacturing costs.

The information disclosed in this Background of the Invention section is only for the enhancement of understanding of the background of the invention and should not be taken as an acknowledgment or any form of suggestion that this information forms a prior art that would already be known to a person skilled in the art.

### BRIEF SUMMARY OF THE INVENTION

Various aspects of the present invention provide an optical filter for a display device in which a plurality of characteristic functional layers, particularly, an Electromagnetic Interference (EMI) shielding layer, and a color control layer, are formed directly on a base substrate without using an additional transparent support film, thereby significantly simplifying a manufacturing process, improving productivity, and reducing manufacturing costs.

In an aspect of the present invention, the optical filter may include a base substrate, an EMI shielding coating formed directly on an upper surface of the base substrate to filter out electromagnetic interference, and a color control resin coating applied directly on a lower surface of the base substrate or on an upper surface of the electromagnetic interference shielding coating. The color control resin coating contains a color control material to perform color control.

In an exemplary embodiment of the invention, the EMI shielding coating may include multiple layers of high-refractivity transparent film and metal thin film, which are stacked repeatedly on one another. The color control resin coating may be applied directly on the upper surface of an uppermost one of the metal thin films of the EMI shielding coating.

In an exemplary embodiment of the invention, the color control resin coating may be applied directly on the upper surface of the EMI shielding coating.

In an exemplary embodiment of the invention, the color control resin coating may contain a conductive material.

In an exemplary embodiment of the invention, the color control resin coating may contain an antistatic agent.

In an exemplary embodiment of the invention, the optical filter may further include a color resin frame formed along the outer circumference thereof.

In an exemplary embodiment of the invention, the color resin frame may be formed on an upper or lower surface of the color control resin coating.

In an exemplary embodiment of the invention, the color resin frame may be a resin coating that is formed along the outer circumference of the optical filter or a resin tape that is bonded along the outer circumference of the optical filter.

In an exemplary embodiment of the invention, the color resin frame may contain one or more selected from among a black colorant, a chromatic colorant, and a fluorescent colorant.

According to the exemplary embodiments of the present invention as set forth above, it is possible to simplify a manufacturing process, improve productivity, and reduce manufacturing costs by directly forming the EMI shielding coating, capable of blocking EMI and NIR, on the base substrate and directly applying a resin, which contains a color control material mixed therein, on the EMI shielding coating.

In particular, it is possible to significantly reduce the processing time because the autoclave process can be obviated. In addition, it is possible to reduce manufacturing costs by preventing the waste of adhesive, release films, etc.

The conductive film type EMI shielding coating is used to block both EMI and NIR without using an additional NIR cutting coating. In addition, it is possible to effectively compensate for the low level of the EMI shielding performance of the conductive film, which may be regarded as a drawback of the conductive film, by adding a conductive material into the color control resin coating. Accordingly, NIR cutting performance can also be effectively achieved without sacrificing EMI shielding performance.

The color control resin coating, that is, a resin layer containing a color control material, is used to perform the color control function as well as act as a protective layer that protects the conductive film type EMI shielding coating, which is vulnerable to moisture and the like. Accordingly, respective constitutional layers can systematically realize improvement.

Furthermore, it is possible to advantageously minimize optical interference and thus ensure excellent transmission and image quality by reducing the number of layers constituting the optical filter, which is located in front of the display panel.

The methods and apparatuses of the present invention have other features and advantages which will be apparent from, or are set forth in more detail in, the accompanying drawings, which are incorporated herein, and the following Detailed Description of the Invention, which together serve to explain certain principles of the present invention.

### BRIEF DESCRIPTION OF THE DRAWINGS

FIG. 1 is a cross-sectional view showing an optical filter for a display device of the related art;

FIG. 2 is an exploded perspective view showing a display device according to a first exemplary embodiment of the invention; and

FIGS. 3 to 6 are cross-sectional views showing optical filters for a display device according to second to fifth exemplary embodiments of the invention.

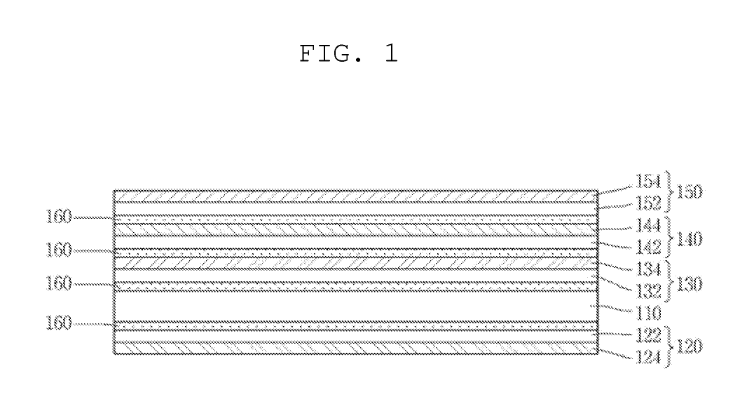

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments thereof, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

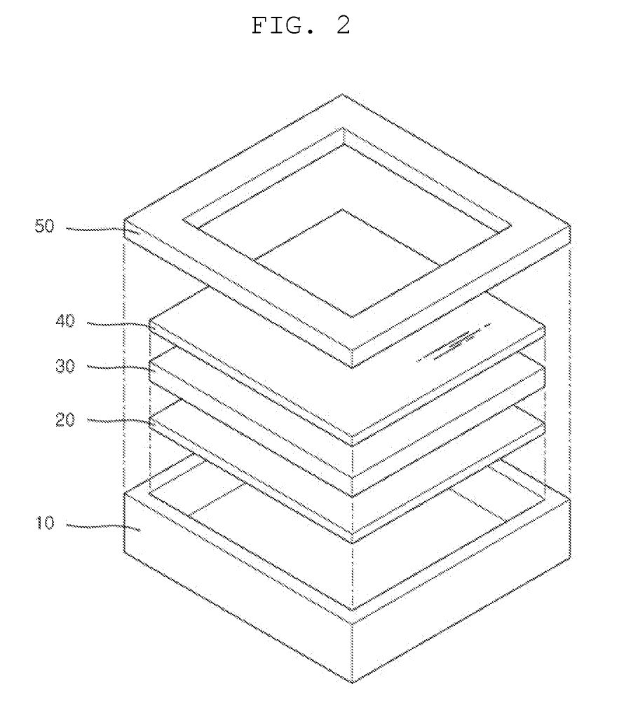

FIG. 2 is an exploded perspective view showing a display device according to a first exemplary embodiment of the invention.

The display device according to the first exemplary embodiment of the invention includes a case 10, a cover 50 covering the upper portion of the case 10, a drive circuit board 20 housed inside the case 10, a display panel 30 including discharge cells, which generate gas discharge therein, and an optical filter 40.

FIG. 3 is a cross-sectional view showing an optical filter for a display device according to a second exemplary embodiment of the invention.

The optical filter according to the second exemplary embodiment of the invention includes a base substrate 310, an Electromagnetic Interference (EMI) shielding coating 320 formed directly on the upper surface of the base substrate 320, and a color control resin coating 330 applied directly on the upper surface of the EMI coating 320 or on the lower surface of the base substrate 310.

Herein, it should be understood that the terms “upper surface” and “lower surface” are used merely with respect to the accompanying drawings. In an actual display device, the upper surface can be, for example, the front surface, which faces the viewers, or the rear surface, which faces the display panel.

It is preferable for the base substrate 310 to have high transparency and heat resistance. As for transparency, it is advantageous for the transmittance of the base substrate 310 to visible light to be 80% or more. As for heat resistance, it is preferable for the glass transition temperature of the base substrate 310 to be 60° C. or more.

The base substrate 310 can be made of an inorganic compound, such as tempered glass, heat-strengthened glass, quartz, etc. or a transparent organic polymer.

The polymer is required to be transparent in the range of visible light. Available examples of such a polymer may include, but are not limited to, acryl, polyethyleneterephthalate (PET), polysulfone (PS), polyethersulfone (PES), polystyrene, polyethylene naphthalate, polyarylate, polyetheretherketone (PEEK), polycarbonate (PC), polypropylene (PP), polyimide, triacetylcellulose (TAC), polymethylmethacrylate (PMMA), and the like. Among these examples, PET is preferable in terms of price, heat resistance, and transparency.

The EMI shielding coating 320 is preferably a conductive film, which can block both EMI and NIR. The conductive film-type EMI shielding coating 320 has a function of blocking strong NIR generated from the display panel 30, which causes electronic devices, such as mobile phones and remote controls, to malfunction. The conductive film-type EMI shielding coating 320 protects the viewers from EMI generated from the display panel 30 by absorbing it and then discharging it to a ground such as the case.

Typically, the conductive film is formed by repeatedly stacking a high-refractivity transparent film and a metal thin film using a deposition process such as sputtering.

The stacked structure of the conductive film and the material of each layer can be modified into various forms. For example, Korean Patent Application Publication Nos. 1997-0073950, 2003-0093734, 2004-0003098, 2004-0003241, 2004-0021177, 2005-00022741, 2006-0034053, 2006-0126162, 2007-0067772, and 2009-0064321 disclose a variety of stacked structures of conductive films and available materials for respective layers in the related art.

All of the stacked structures and the materials of respective layers in the related art, including the conductive films disclosed in the above-identified published patent documents, can be applied to the present invention. For example, an available conductive film includes multiple layers of high-refractivity transparent film made of Indium Tin Oxide (ITO) and metal thin film made of Ag, which are stacked repeatedly on one another, and an additional ITO high-refractivity transparent film formed as an uppermost layer.

A protective film can be interposed between the high-refractivity transparent film and the metal thin film. For example, an available conductive film includes multiple layers of high-refractivity transparent film made of niobium oxide (Nb₂O₅), protective film made of Aluminum Zinc Oxide (AZO), metal thin film made of Ag, and protective film made of AZO, which are stacked repeatedly on one another, and an additional Nb₂O₅ high-refractivity transparent film formed as an uppermost layer.

Here, Au, Cu, Pt, Pd, or the like can be used as a substitute for Ag. In addition, indium oxide (In₂O₃), stannic oxide (SnO₂), zinc oxide (ZnO), or the like can be used in place of ITO. In addition, ZnO, SnO₂, ITO, or the like can be used in place of AZO.

The compositions of the respective high-refractivity transparent films and the respective metal thin films can be the same as or different from each other.

The optical filter of this embodiment does not need a transparent support film, such as a PET film, or an adhesion layer since the conductive film-type EMI shielding coating 320 is directly formed on the base substrate 310. This can consequently simplify a fabrication process, improve productivity, and reduce manufacturing costs.

The color control resin coating 330 is preferably applied on the EMI shielding coating 320. This allows the color control resin coating 330 to protect the conductive film-type EMI shielding coating which is vulnerable to moisture, oxidation, or the like.

The resin used in the color control resin coating 330 is preferably a thermosetting resin that cures when heated. The test result showed that the reliability of heat and moisture resistance can equal that of a conventional optical filter. From this, it was appreciated that the conductive film could be effectively protected using the thermosetting resin. However, the present invention is not limited thereto.

The color control resin coating 330 can perform a color control function. The color control resin coating can contain a color adjusting colorant and/or a neon-cut colorant in a resin.

The color adjusting colorant can serve to vary or control color balance by reducing or adjusting the amount of red (R), green (G), and blue (B).

The neon-cut colorant can perform a neon-cut function. A PDP device has a drawback that Red visible light tends to look orange. The neon-cut colorant according to an exemplary embodiment of the invention serves to block orange light with a wavelength ranging from 580 to 600 nm, thereby lowering the transmittance within the wavelength range below a predetermined value.

The color control resin coating 330 uses a variety of colorants in order to increase the range of color reproduction of the display and to improve the image clearness. Such colorants can be dyes or pigments.

Such colorants include organic colorants having a neon-cut function, such as anthraquinones, cyanines, azos, phthalocyanines, methines, and the like. However, the present invention is not limited thereto. The kind and concentration of the colorants are not limited to specific values since they are determined by the absorption wavelengths and absorption coefficients of the colorants, as well as the transmission characteristics required by displays.

The color control resin coating 330 can also contain an NIR cutting colorant in addition to the above-described color adjusting colorant and/or neon-cut colorant.

In addition, the color control resin coating 330 can contain a conductive material. Recently, the market for full High Definition (HD) TVs is growing due to the advancement of display devices. Accordingly, a higher level of EMI shielding performance is required.

In an exemplary embodiment of the invention, in order to compensate for the low level of the EMI shielding performance of the conductive film type EMI shielding coating, the color control resin coating contains a conductive material. The conductive material in the color control resin coating can improve EMI shielding performance by reducing the surface resistance of the entire optical filter. Accordingly, the conductive film type EMI shielding coating can be applied to full HD TVs.

In addition, it is possible to advantageously improve productivity and reduce manufacturing costs by reducing the use of Ag in the EMI shielding coating.

Available examples of the conductive material may include carbon nano-tubes, metal powder, metal oxide powder and the like. Herein, the metal powder may be composed of one or more selected from among Co, Al, Zn, Zr, Pt, Au, Pd, Ti, Fe, Sn, In, Ni, Mo, W, Ag, Cu, and the like. The metal oxide powder may be composed of one or more selected from among copper oxide, zinc oxide, indium oxide, tin oxide, ITO, AZO, Indium Zinc Oxide (IZO), and the like. In addition, the conductive material can be one or more polymers selected from among polythiophene, polypyrrole, polyaniline, li(3,4-ethylenedioxythiophene), poly(3-alkylthiophene), polyisothianaphthene, poly(p-phenylene vinylene), poly(p-phenylene), and derivatives thereof.

The color control resin coating may contain an antistatic agent. Antistatic performance of 1×10¹³ Ω/sq or less can be obtained by adding particles of, for example, Antimony Tin Oxide (ATO), AZO, and ITO as the antistatic agent.

In an exemplary embodiment of the invention, it is possible to prevent the waste of adhesive, release films, etc., since the EMI shielding coating and the color control resin coating are formed by a direct coating process, thereby reducing manufacturing costs. Typically, a conventional color control film is supplied to an optical filter manufacturer in the state in which a PET transparent support film, a color control layer, and an adhering layer as well as a release film are integrally stacked on one another. The optical filter manufacturer adheres the color control film onto an optical filter after removing the release film from the color control film. As such, the release film, etc. are wasted, thereby causing an increase in manufacturing costs. In contrast, this embodiment of the invention removes this source of the increase in manufacturing costs by directly applying the color control resin coating on the optical filter.

In addition, it is also possible to minimize optical interference by reducing the number of layers constituting the optical filter, thereby providing excellent image quality.

After being adhered, the conventional color control film is essentially processed in an autoclave, which takes from about 30 minutes to one hour. In contrast, in this embodiment of the invention, it takes only 5 to 10 minutes to form the color control resin coating, thereby significantly reducing processing time.

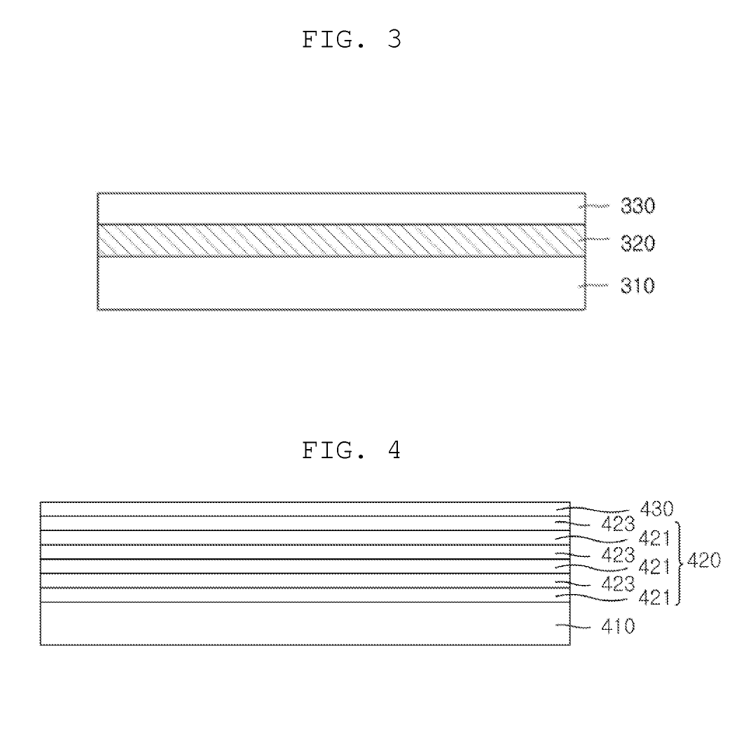

FIG. 4 is a cross-sectional view showing an optical filter for a display device according to a third exemplary embodiment of the invention.

The optical filter shown in FIG. 4 has a structure in which the uppermost high-refractivity transparent film is replaced by a color control resin coating, which differentiates it from a conventional conductive film. The color control resin coating can be regarded as a constitutional layer of an EMI shielding coating. The color control resin coating is applied directly on the outer surface of the outermost one of a plurality of metal thin films 423. It is preferable that the color control resin coating, which replaces the high-refractivity transparent film, also have a high refractive index. The reference numeral 421 designates a high-refractivity transparent film.

A novel structure of hybrid display filter, in which the color control resin coating is integrated with the EMI shielding coating, is provided. Specifically, the hybrid coating, which has the multiple functions of the EMI shielding coating and the color control resin coating, is formed on the base substrate 410 by a direct coating process. Accordingly, it is possible to simplify the process and reduce manufacturing costs.

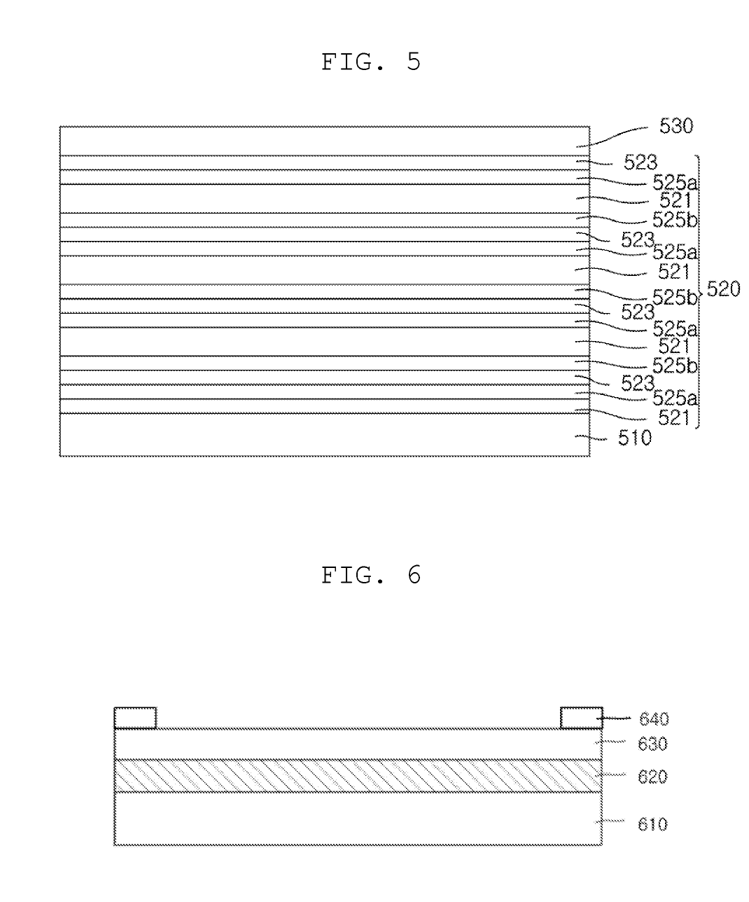

FIG. 5 is a cross-sectional view showing an optical filter for a display device according to a fourth exemplary embodiment of the invention.

As in the foregoing embodiment shown in FIG. 4, an EMI shielding coating 520 shown in FIG. 5 includes multiple layers of high-refractivity transparent film 521 and metal thin film 523, which are stacked repeatedly on one another. In addition, protective films 525a and 525b are interposed alternately between the high-refractivity transparent films 521 and the metal thin films 523.

Typically, the high-refractivity transparent film contains niobium oxide (Nb₂O₅). The high-refractivity transparent film can be composed only of Nb₂O₅, or can contain a small amount of elements other than Nb₂O₅. The other elements may include, for example, Ti, Cr, and Zr.

The compositions of the respective high-refractivity films can be the same as or different from each other.

The refractive index of the high-refractivity transparent film can be higher than that of air (i.e., about 1.5), and is preferably 2 or more.

The first protective film 525a is formed on the high-refractivity transparent film 521. The first protective film 525a is typically made of an oxide, the composition of which includes a small amount of Al or Al₂O₃ contained in ZnO. (Herein, the oxide is referred to as “AZO.”) For example, the ratio of ZnO to Al₂O₃ can range from 90:10 to 99.9:0.1, but the present invention is not limited thereto.

When the first protective film composed of AZO is formed by sputtering, a target containing a small amount of aluminum oxide mixed into zinc oxide is used and the sputtering is performed supplying an inert gas without supplying an oxidizing gas. It is not required to supply the oxidizing gas such as O₂ since the transparency of the first protective film composed of AZO does not decrease even if the oxidizing gas is not supplied. Accordingly, during the formation of the metal thin film 523, the problem of oxidation of the metal thin film 523 does not occur. The first protective film 525a serves to improve durability by protecting the metal thin film 523 that is formed on the first protective film. In addition, the first protective film 525a improves EMI shielding performance by raising electric conductivity, which is mainly realized by the metal thin film.

The first protective film 525a reduces the loss of visible light caused by light absorption due to surface Plasmon, by suppressing the generation of surface Plasmon, which would otherwise be generated at the interface between the Nb₂O₅ high-refractivity transparent film 521 and the metal thin film 523. At the same time, the first protective film 525a serves to reduce the reflectance of visible light and increase a wavelength band in which the reflectance is low.

The compositions of the respective first protective films can be the same as or different from each other.

In some cases, however, the first protective film 525a can be excluded from the EMI shielding coating.

Next, the metal thin film 523 is formed on the first protective film. The metal thin film is made of Ag or an alloy containing Ag as a major component (90% Ag or more by weight). Ag has excellent ductility and conductivity and can maintain excellent conductivity even in the form of a thin film. In addition, Ag is inexpensive and advantageously absorbs less visible light than other metals, thereby enabling easy formation of a transparent thin film.

Regardless of such merits, the use of Ag as a metal thin film has been limited since it is vulnerable to chemicals. Due to the first protective film 525a formed on one surface of the metal thin film 523, the durability of the EMI shielding coating is not lowered even if the metal thin film is made of Ag.

The compositions of the respective metal thin films can be the same as or different from each other.

The second protective film 525b acts as a blocker that prevents the metal thin film 523 from losing electric conductivity due to oxygen plasma during the subsequent process of forming the high-refractivity transparent film 521. This is because, if direct current sputtering is performed to form the high-refractivity transparent film on the metal thin film after the metal thin film is formed, the previously-formed metal thin film can be damaged by the oxygen plasma.

Such second protective films are typically made of AZO.

The compositions of the second protective films can be the same as or different from each other.

The second protective film 525b reduces the loss of visible light in the EMI shielding coating, caused by light absorption due to surface Plasmon, by suppressing the generation of surface Plasmon, which would otherwise be generated at the interface between the metal thin film and the high-refractivity transparent film. At the same time, the second protective film 525b serves to reduce the reflectance of visible light and increase a wavelength band in which the reflectance is low.

In some cases, the second protective film 525b can be excluded from the EMI shielding coating.

A color control resin coating 530 is applied on the upper surface of the uppermost one of the metal thin films 523. Preferably, the color control resin coating 530 has a high refractive index.

FIG. 6 is a cross-sectional view showing an optical filter for a display device according to a fifth exemplary embodiment of the invention.

The optical filter shown in FIG. 6 includes a base substrate 610, an EMI shielding coating 620, a color control resin coating 630, and a color resin frame 640. The color resin frame 640 replaces a black frame of the related art.

The frame of a conventional optical filter is formed by printing black paste along the circumference of the optical filter. Contrasted with an effective screen, the black frame raises the contrast on the effective screen inside the black frame. In addition, the black frame itself provides an esthetic sense, thereby improving visual quality.

With respect to a fabrication process, the frame is produced by printing black paste on one side of a base substrate and then tempering it. As a result, the printing and tempering of the black paste lead to an increase in manufacturing costs, a complicated fabrication process, and an increase in processing time. In addition, manufacturers have to construct printing and tempering facilities and the related infrastructure. Furthermore, the black frame fails to meet consumers' demand for a variety of designs.

In an exemplary embodiment of the invention, it is possible to solve the above-mentioned problems by forming the color resin frame 640 in place of the conventional black frame.

It is possible to reduce manufacturing costs, simplify a process, and reduce processing time by employing a resin coating process or a resin tape bonding process in place of the conventional processes of printing and tempering black paste.

In particular, it is possible to significantly raise process efficiency by forming the color control resin coating 630 and the color resin frame 640 through continuous in-situ coating. The merits will be more apparent through the following comparison with a conventional optical filter having a black frame and color control film.

In order to fabricate the conventional optical filter, a separate process of fabricating the color control film has to be preceded. Describing all of the process (except for the process of forming an EMI shielding film), the four process steps are sequentially performed in the following order: Fabricating the color control film→Printing of black paste on the base substrate→Tempering the base substrate on which the black paste is printed→Adhering the color control film to the base substrate. In respective process steps, objects are carried to respective facilities, and to perform the main process, setting, alignment, and the like have to be preceded. (Most optical filter manufacturers purchase color control films from other companies rather than manufacturing the color control films themselves. This is one of the reasons for the increase in manufacturing cost. In addition, manufacturing cost is further increased since the optical filter manufacturers also purchase a base substrate on which the black frame is formed, rather than performing the ceramic printing and curing processes themselves.)

In contrast, the optical filter according to an exemplary embodiment of the invention can significantly raise process efficiency since corresponding processes can be finished by repeating twice the resin coating in situ. In addition, it is possible to reduce investment in facilities and infrastructure by eliminating the black paste printing and tempering facilities. That is, it is possible to reduce the costs for the facilities and the infrastructure by applying the color resin frame 640 using the facilities for applying the color control resin coating 630.

The optical filter can have a conductive tape bonded along the outer circumference thereof. The conductive tape is used to ground EMI, which is trapped by the EMI shielding coating. It is also possible to reduce the costs for the facilities and the infrastructure by bonding the tape-type color resin frame 640 using the conductive tape bonding facilities.

In addition, it is possible to add black, chromatic and/or fluorescent colorants into the color resin frame 640, and thus, to use the color resin frame 640 as a design differentiation factor to meet the desire of consumers for a variety of designs. Recently, the outer design of display devices has come to be regarded as the most important competitive factor. Accordingly, the outer design of the optical filter, which is exposed on the front of the display device, is gaining attention. However, due to the characteristics of the optical filter through which light of image passes, the design of the effective screen has been limited. Accordingly, the importance of stimulating the desire of consumers to purchase by providing a distinctive design of the frame for the optical filter, as in this embodiment, cannot be overstated.

The color resin frame 640 is formed along the outer circumference of the optical filter. FIG. 6 shows an exemplary embodiment in which the color resin frame 640 is applied on the upper surface of the color control resin coating 630. In this case, it is possible to finish an intended process by repeating in-situ resin coating twice, thereby significantly improving process efficiency. However, the present invention is not limited thereto. The color control resin coating and the color resin frame can be formed spaced apart from each other.

The color resin frame 640 has a color. As described above, the color resin frame 640 can contain a black colorant, a chromatic colorant, a fluorescent colorant, and/or a variety of other colorants, and can provide various impressions.

The color resin frame 640 contains a resin. The color resin frame 640 can be applied along the outer circumference of the optical filter using a mask. A tape-type color resin frame is bonded to the outer circumference of the optical filter. As a tape type color resin frame, an anti-reflection high-blackness tape or a color tape is bonded along the four outer edges of the optical filter.

Although exemplary embodiments of the present invention have been described in which the optical filter includes the base substrate, the EMI shielding coating, and the color control resin coating, a variety of other functional films or layers can be added as constitutional layers of the optical filter for a display device of the invention. For example, an optical filter for a display device according to an exemplary embodiment of the invention may also include an anti-reflection layer, an external light shielding layer, an anti-glare layer, an NIR cutting layer, and the like.

In addition, although the PDP optical filter and the PDP device have been illustrated above, the present invention is not limited thereto. The optical filter of the invention is applicable to a variety of display devices including i) large display devices such as a PDP device, an Organic Light-Emitting Diode (OLED) device, a Liquid Crystal Display (LCD), and a Field Emission Display (FED); ii) small mobile display devices such as a Personal Digital Assistant (PDA), a display window of a small game machine, a display window of a mobile phone, and the like; and iii) a flexible display device and the like.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. An optical filter for a display device, comprising:
a base substrate;
an electromagnetic interference shielding coating formed directly on an upper surface of the base substrate to filter electromagnetic interference; and
a color control resin coating applied directly on a lower surface of the base substrate or an upper surface of the electromagnetic interference shielding coating, wherein the color control resin coating contains a color control material to perform color control.

2. The optical filter according to claim 1, wherein the electromagnetic interference shielding coating comprises a conductive film including multiple layers of high-refractivity transparent film and metal thin film, which are stacked repeatedly on one another, and an additional high-refractivity transparent film formed as an uppermost layer.

3. The optical filter according to claim 1,
wherein the electromagnetic interference shielding coating includes multiple layers of high-refractivity transparent film and metal thin film, which are stacked repeatedly on one another, and
wherein the color control resin coating is applied directly on an upper surface of an uppermost one of the metal thin films of the electromagnetic interference shielding coating.

4. The optical filter according to claim 3, wherein each of the multiple layers of high-refractivity transparent film and metal thin film includes a protective film interposed between the high-refractivity transparent film and the metal thin film.

5. The optical filter according to claim 4, wherein the high-refractivity transparent film contains niobium oxide, the metal thin film contains Ag or an Ag alloy, and the protective film contains aluminum zinc oxide.

6. The optical filter according to claim 3, wherein the color control resin coating has a high refractive index.

7. The optical filter according to claim 2, wherein the color control resin coating is applied directly on the upper surface of the electromagnetic interference shielding coating.

8. The optical filter according to claim 1, wherein the color control resin coating includes a thermosetting resin.

9. The optical filter according to claim 1, wherein the color control material includes at least one of a color adjusting colorant and a neon-cut colorant.

10. The optical filter according to claim 1, wherein the color control resin coating includes a conductive material.

11. The optical filter according to claim 10, wherein the conductive material includes at least one selected from the group consisting of carbon nano-tubes, metal powder, and metal oxide powder.

12. The optical filter according to claim 1, wherein the color control resin coating contains an antistatic agent.

13. The optical filter according to claim 1, further comprising a color resin frame formed along an outer circumference of the optical filter.

14. The optical filter according to claim 13, wherein the color resin frame is formed on an upper or lower surface of the color control resin coating.

15. The optical filter according to claim 13, wherein the outer circumference of the optical filter is coated with the color resin frame.

16. The optical filter according to claim 13, wherein the color resin frame comprises a tape that is bonded along the outer circumference of the optical filter.

17. The optical filter according to claim 13, wherein the color resin frame contains a black colorant.

18. The optical filter according to claim 13, wherein the color resin frame contains at least one of a chromatic colorant and a fluorescent colorant.

19. A display device comprising an optical filter, wherein the optical filter comprises:
a base substrate;
an electromagnetic interference shielding coating formed directly on an upper surface of the base substrate to filter electromagnetic interference; and
a color control resin coating applied directly on a lower surface of the base substrate or an upper surface of the electromagnetic interference shielding coating, wherein the color control resin coating contains a color control material to perform color control.
